(19) United States
(12) Patent Application Publication
(10) Pub. No.: US 2024/0319613 A1
(43) Pub. Date: Sep. 26, 2024

(54) METHOD FOR OPTIMIZING A PUPIL STOP SHAPE FOR SIMULATING ILLUMINATION AND IMAGING PROPERTIES OF AN OPTICAL PRODUCTION SYSTEM DURING THE ILLUMINATION AND IMAGING OF AN OBJECT BY MEANS OF AN OPTICAL MEASUREMENT SYSTEM

(71) Applicant: Carl Zeiss SMT GmbH, Oberkochen (DE)

(72) Inventor: Alexander Winkler, Oberkochen (DE)

(21) Appl. No.: 18/733,981

(22) Filed: Jun. 5, 2024

Related U.S. Application Data
(63) Continuation-in-part of application No. PCT/EP2022/084351, filed on Dec. 5, 2022.

(30) Foreign Application Priority Data
Dec. 6, 2021 (DE) 102021213827.6

(51) Int. Cl. G03F 7/00; G03F 1/84; G03F 7/025

(52) U.S. Cl. CPC G03F 7/70504; G03F 1/84; G03F 7/025

(57) ABSTRACT

In order to simulate properties of an optical production system, use is made of an optical measurement system comprising an illumination optical unit for an object to be imaged having a pupil stop in the region of an illumination pupil and an imaging optical unit for imaging the object. In order to optimize a pupil stop shape of the pupil stop, firstly a starting stop shape of the pupil stop is predefined as an initial design candidate for the simulation. The starting stop shape is modified and at least one fabrication boundary condition of the corresponding modification stop shape is checked. The steps “modifying” and “checking” are repeated until the checking reveals compliance with the boundary conditions. A match quality between the properties of the optical production system and those of the optical measurement system is determined and the steps “modifying”, “checking” and “determining” are repeated until the match quality attains a predefined optimization criterion, which is queried. A target stop shape resulting from the target stop shape that occurred with the smallest merit function value E in the optimization is fabricated as an optimized pupil stop shape after attaining the optimization criterion. This results in simulation—as free of deviations as possible—of the illumination and imaging properties of the optical production system during the illumination and imaging of the object by use of the optical measurement system.

### CROSS-REFERENCE TO RELATED APPLICATIONS

The present patent application is a continuation-in-part of and claims priority under 35 U.S.C. § 120 from PCT Application No. PCT/EP2022/084351, filed on Dec. 5, 2022, which claims the priority of German patent application DE 10 2021 213 827.6, filed on Dec. 6, 2021. The entire contents of each of these priority applications are incorporated herein by reference.

### TECHNICAL FIELD

The invention relates to a method for optimizing a pupil stop shape for simulating illumination and imaging properties of an optical production system during the illumination and imaging of an object by use of an optical measurement system. Furthermore, the invention relates to a pupil stop optimized by use of such a method, and to a metrology system comprising at least one such pupil stop.

### BACKGROUND

A metrology system for measuring an aerial image of a lithography mask in three dimensions is known from WO 2016/012425 A2 and WO 2016/012426 A1. A corresponding metrology system and a method for determining an aerial image of a lithography mask in three dimensions are known from DE 10 2019 206 651 A1. DE 10 2013 219 524 A1 describes a device and a method for determining an imaging quality of an optical system, and an optical system. DE 10 2013 219 524 A1 has described a phase retrieval method for determining a wavefront on the basis of the imaging of a pinhole. DE 10 2017 210 164 B4 describes a method for adjusting an imaging behaviour of a projection lens, and an adjustment apparatus. A method for compensating for lens heating in a projection exposure apparatus is known from U.S. Pat. No. 9,746,784 B2. An optical production system, in particular having an anamorphic projection optical unit, is known for example from US 2020/0272058 A1. Further variants of optical production systems are known from WO 2009/100856 A1. DE 10 2008 001 553 A1 discloses a component to set a scan integrated illumination energy in an object plane of a microlithography projection exposure apparatus. EP 0 674 778 B1 discloses a process and a device for generating dosage patterns for the production of structured surfaces. DE 103 52 040 A1 and WO 2005/045503 A1 disclose a stop and/or filter arrangement for optical devices, in particular for microscopes.

The known metrology systems, in regard to the set-up of their illumination optical unit and/or the set-up of their imaging optical unit, differ in some instances greatly from the set-up of corresponding illumination and imaging optical components of the optical production systems to be simulated. This is owing to the fact, in particular, that the set-up of the metrology system cannot be effected with the same outlay in terms of design and energy as that expended for the set-up of the optical production system.

### SUMMARY

It is therefore an aspect of the present invention to provide an optimization method for a pupil stop shape for use in a metrology system which results in a simulation—as free of deviations as possible—of the illumination and imaging properties of the optical production system during the illumination and imaging of the object by use of the optical measurement system of the metrology system, despite the differences present in the illumination and imaging optical components.

This aspect is achieved according to the invention by use of an optimization method having the features specified in claim 1.

According to the invention, it has been recognized that in particular the mathematical or numerical modelling of optical systems makes it possible for effects of a change in a stop shape of a pupil stop on illumination and imaging properties of an optical system to be determined overall qualitatively with such precision that a stop shape optimization is made possible by this means. The target stop shape that results in the course of the final fabrication step of the optimization method ensures a simulation of the illumination and imaging properties of the optical production system during the illumination and imaging of the object by use of the optical measurement system with high precision. Even complex illumination settings of the optical production system and/or complex imaging properties of the optical production system, for example an anamorphic imaging of a projection optical unit of the optical production system, can be taken into account and simulated during the match quality determination during the optimization method. For the anamorphic imaging of a projection optical unit, reference is made to U.S. Pat. No. 9,366,968 B2. In particular, an illumination-side pupil obscuration of the optical measurement system that is necessary owing to structural specifications, for example, can be taken into account during the optimization method. This illumination-side obscuration of the optical measurement system can then be corrected or compensated for by way of the target stop shape. Even effects of necessary webs that are required in the mechanical construction of the pupil stop of the optical measurement system can be taken into account. Specifications in regard to a self-supporting configuration of the stop shape, a minimum stop web width, a minimum stop hole diameter, and a maximum curvature of a stop edge portion can be taken into account when checking the fabrication boundary conditions. This avoids a situation in which optimization solutions are found which cannot be fabricated. Even an in particular central obscuration-often to be found in the optical production system—of an exit pupil of the imaging optical unit of the optical production system can be taken into account in the context of the optimization method. In this case, a central obscuration of the exit pupil of the optical production system can be taken into account by way of a central stop of an NA aperture stop in the imaging optical unit of the measurement system. Even different imaging exit pupil apodizations between the optical production system, on the one hand, and the optical measurement system, on the other hand, can be taken into account.

The optimization method can be implemented such that in particular a structural configuration of the object to be imaged is taken into account. Optical properties that change in relation to different structures can thus be taken into account.

Differences between a configuration of an illumination pupil of the optical production system, which is regularly constructed from a multiplicity of individual spots, and an illumination pupil of the optical measurement system of the metrology system, which regularly has continuous illuminated regions, can likewise be taken into account.

Alternatively, the optimization method can also function such that a specific object structure does not influence the method. Particularly optical production systems having a large image-side numerical aperture (image-side numerical aperture greater than 0.5) can be simulated with good quality.

A checking method for checking compliance with fabrication boundary conditions according to claim 2 has proved to be worthwhile in practice. Requirements in respect of a fabrication quality can be predefined by way of predefining a size of the surrounding regions respectively checked. This avoids in particular a situation in which excessively narrow webs or excessively great curvatures of the stop edge arise along the respective check portions, i.e. after checking has taken place along an entire stop edge, of the target stop shape.

A pixel-by-pixel arrangement of pixels of the surrounding regions which are checked during the checking of the fabrication boundary conditions, according to claim 3, has proved to be worthwhile in practice. A size of the pixels can be chosen according to the attainable fabrication resolution.

Instead of pixel-based checking of fabrication boundary conditions for the pupil stop shape, polygon boundaries can be used as desired boundary shapes; in such a case, a curvature estimation (rounding radius of the stop shape) can be derived from angles of polygon line segments respectively adjoining one another.

Taking account of a pupil match between the optical production system, on the one hand, and the optical measurement system, on the other hand, according to claim 4, has proved to be worthwhile for ensuring a sufficient match quality determination. Information of the respective illumination pupil and/or of the respective imaging pupil can be used here depending on the boundary conditions of the optical systems involved.

A merit function value calculation according to claim 5 simplifies a numerical modelling of the match quality determination in the context of the optimization method. A size of the pupil overlap region can be varied in the context of the determination. This can be done depending on the chosen boundary conditions of the optical systems involved. A degree of the required match quality can be finely influenced by way of predefining the size of the pupil overlap regions used when determining the match quality, and their number and distribution over the illumination pupil. This predefinition can be effected in particular depending on the illumination and imaging properties of the optical production system that are to be simulated.

Instead of an overlap-based merit function, a match quality can also be effected by way of a direct imaging simulation for a large number of test imagings taken into account. In the context of such direct imaging simulations, directly corresponding imaging parameters, in particular the deviation of a critical dimension (CD) or an imaging telecentricity, can be evaluated and a match between the optical production system and the optical measurement system can be ensured.

Illumination and imaging parameters according to claim 6 have proved to be worthwhile in practice since they are well adapted to typical imaging properties or imaging aberrations of the optical systems involved. Further illumination and imaging parameters can also be used, for example a parameter that compares possible structure resolutions (critical dimensions, CDs) along two mutually perpendicular coordinates with one another. One example of such a parameter is the so-called HV (horizontal/vertical) asymmetry. A parameter that predefines a lower limit for a pupil transmission can also be used in the context of the match quality determination.

An optimization loop according to claim 7 makes it possible to use known optimization methods. One example thereof is simulated annealing. Other optimization methods known in the technical literature can also be used. A total computation time or else a quality of compliance with the optimization criterion can be chosen as a termination criterion.

Taking account of a field dependence of the object illumination according to claim 8 improves the simulation of the illumination and imaging properties of the optical production system. The field dependence can be taken into account by averaging the pupils of the optical production system over the respective field and/or by determining a match quality in the context of the optimization method for all field points or for selected field point regions.

The advantages of a pupil stop according to claim 9 correspond to those which have already been explained above with reference to the optimization method according to the invention.

In the case of a freeform pupil stop according to claim 10, this affords correspondingly many degrees of freedom of design for simulating the optical properties of the production system. A freeform pupil stop is a pupil stop whose stop boundary does not have a distinguished axis of symmetry and/or plane of symmetry. Even a multifold rotational symmetry is not present in the case of a freeform pupil stop.

The advantages of a metrology system according to claim 11 correspond to those which have already been explained above with reference to the optimization method and the pupil stop optimized thereby.

An interchange holder according to claim 12 makes it possible to use different pupil stops in the optical measurement system of the metrology system.

A metrology system having a correspondingly optimized pupil stop has proved to be particularly worthwhile in the use according to claim 13. Different imaging scales of the projection optical unit of the optical production system in mutually perpendicular directions can be taken into account in the context of the fabrication step by use of different scaling in these two directions.

Exemplary embodiments of the invention are explained in more detail below with reference to the drawings, in which:

### BRIEF DESCRIPTION OF DRAWINGS

FIG. 1 shows a very schematic plan view, with a viewing direction perpendicular to a plane of incidence, of a metrology system for simulating a target wavefront of an imaging optical production system when an object is illuminated with illumination light, comprising an illumination optical unit for illuminating the object and an optical measurement system with an imaging optical unit for imaging the object, with the illumination optical unit and the imaging optical unit each being represented very schematically;

FIG. 2 shows a plan view of a sigma stop for arrangement in a pupil plane of the illumination optical unit of the metrology system;

FIG. 3 shows, in an illustration similar to FIG. 2, a plan view of an NA stop for arrangement in a pupil plane of the imaging optical unit of the optical measurement system of the metrology system;

FIG. 4 schematically shows an instantaneous overlap between an illumination pupil and a pupil of the imaging optical unit of an optical system comprising an illumination optical unit and an imaging optical unit, for elucidating a method for optimizing a match quality between the illumination and imaging properties of the optical production system and of the optical measurement system;

FIG. 4A shows an illumination pupil (on the left) and a projection optical unit exit pupil (on the right) of an optical production system which is simulated in regard to its optical properties by way of the metrology system;

FIG. 4B shows a sigma pupil stop shape (on the left) and an NA aperture stop shape (on the right) of the optical measurement system of the metrology system for simulating the pupil configurations according to FIG. 4A which were found in the context of a stop shape optimization method;

FIG. 5 shows a detail of a stop shape of a pupil of the illumination optical unit of the optical measurement system for elucidating a method for checking at least one fabrication boundary condition, with the illustration of a permissible course of a marginal check portion of the stop shape that satisfies the fabrication boundary conditions;

FIG. 6 shows, in an illustration similar to FIG. 5, one example of a check portion of a stop shape that does not satisfy the fabrication boundary conditions;

FIG. 7 shows a flowchart of a method for optimizing a pupil stop shape for simulating the illumination and imaging properties of the optical production system during the illumination and imaging of the object by use of the optical measurement system;

FIG. 8 shows one example of a target stop shape that arises during the optimization method, represented in pupil coordinates (angle space); and

FIG. 9 shows an interrupted detail from a fabrication metal sheet having a target stop shape on the basis of the angle space result according to FIG. 8, with additional alignment marking openings being illustrated.

### DETAILED DESCRIPTION

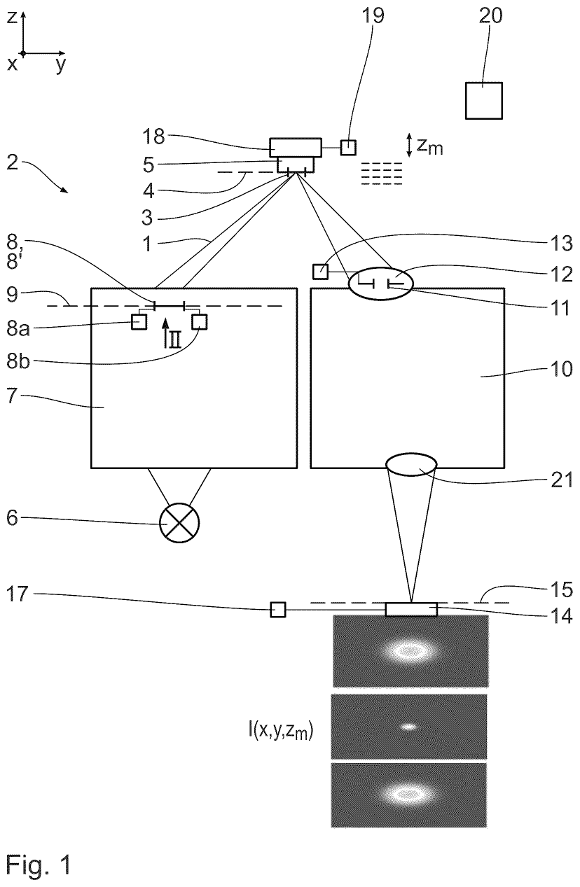

In order to facilitate the presentation of positional relationships, a Cartesian xyz-coordinate system is used hereinafter. In FIG. 1, the x-axis runs perpendicularly to the plane of the drawing and out of the latter. The y-axis runs towards the right in FIG. 1. In FIG. 1, the z-axis runs upwards.

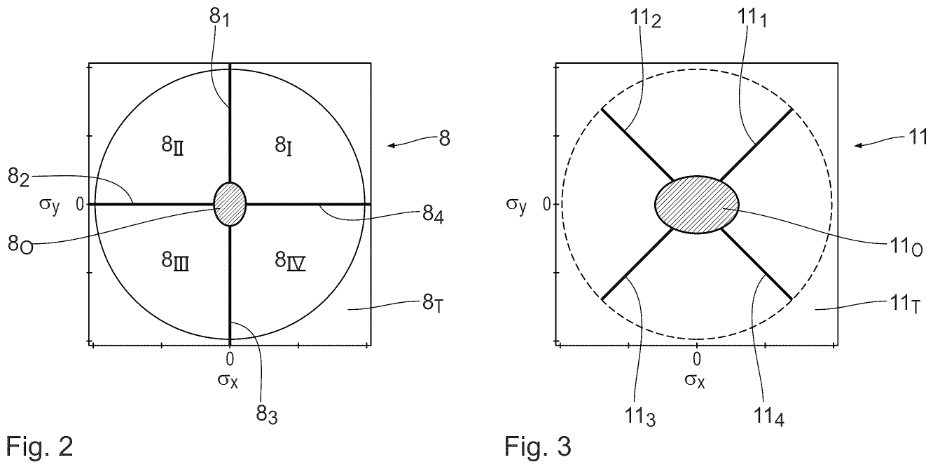

In a view that corresponds to a meridional section, FIG. 1 shows a beam path of EUV illumination light or imaging light 1 in a metrology system 2 for simulation of illumination and imaging properties, in particular of a target wavefront, of an imaging optical production system when an object is illuminated with the illumination light 1. In an imaging optical unit of an optical measurement system of the metrology system 2, a test structure 5 (cf. FIG. 2) in the form of a reticle or a lithography mask arranged in an object field 3 in an object plane 4 is imaged using the EUV illumination light 1. Below, the test structure 5 is also referred to as object or sample.

The metrology system 2 is used to analyze a three-dimensional (3D) aerial image (aerial image metrology system). Applications include the simulation of an aerial image of a lithography mask, in the way that the aerial image would also appear in a producing projection exposure apparatus, for example in a scanner. Such metrology systems are known from WO 2016/012 426 A1, from US 2013/0063716 A1 (cf. FIG. 3 therein), from DE 102 20 815 A1 (cf. FIG. 9 therein) and from DE 102 20 816 A1 (cf. FIG. 2 therein) and from US 2013/0083321 A1.

The illumination light 1 is reflected at the object 5. A plane of incidence of the illumination light 1 lies parallel to the yz-plane.

The EUV illumination light 1 is produced by an EUV light source 6. The light source 6 can be a laser plasma source (LPP; laser produced plasma) or a discharge source (DPP; discharge produced plasma). In principle, a synchrotron-based light source can also be used, for example a free electron laser (FEL). A used wavelength of the EUV light source can range between 5 nm and 30 nm. In principle, in one variant of the metrology system 2, a light source for another used light wavelength can also be used instead of the light source 6, for example a light source for a used wavelength of 193 nm.

Depending on the embodiment of the metrology system 2, the latter can be used for a reflective or else for a transmissive object 5. One example of a transmissive object is a pinhole stop.

An illumination optical unit 7 of the metrology system 2 is arranged between the light source 6 and the object 5. The illumination optical unit 7 serves for the illumination of the object 5 to be examined with a defined illumination intensity distribution over the object field 3 and at the same time with a defined illumination angle distribution with which the field points of the object field 3 are illuminated. This illumination angle distribution is also referred to hereinafter as illumination aperture or illumination setting.

The illumination aperture is delimited by way of a sigma aperture stop 8 of the illumination optical unit 7, which is arranged in an illumination optical unit pupil plane 9 and predefines an illumination pupil there. The sigma aperture stop 8 is also referred to hereinafter as sigma stop. The sigma aperture stop 8 marginally delimits a beam of illumination light 1 which is incident thereon. As an alternative or in addition, the sigma aperture stop 8 and/or the stop in the imaging optical unit can also shadow the illumination light beam from the inside, that is to say act as an obscuration stop. A corresponding stop can have an inner stop body that accordingly shadows the beam on the inside, said stop body being connected to an outer stop support body by way of a plurality of webs, for example by way of four webs.

FIG. 2 shows one embodiment of the sigma stop 8 in a plan view from viewing direction II in FIG. 1. The coordinates σₓ, σ_{y} illustrated in FIG. 2 span the illumination optical unit pupil plane 9 in angle space and correspond to the coordinates x and y in FIG. 1. The sigma illumination stop 8 has four webs 8₁ to 8₄, which extend in the manner of spokes between a marginal stop support 8_{T} and an inner obscuration shadowing body 8₀ and support the latter. Between the webs 8ᵢ, the carrier 8_{T} and the inner obscuration shadowing body 8₀, the sigma stop 8 has four openings 8_{I}, 8_{II}, 8_{III} and 8ᵣₓ corresponding to the four quadrants of the σₓ σ_{y}-coordinate system. An obscurated illumination of the metrology system is predefined by way of the sigma stop 8 according to FIG. 2.

The sigma aperture stop 8 is displaceable by way of a displacement drive 8a in the illumination optical unit pupil plane 9, that is to say parallel to the xy-plane, in a defined fashion. The stop displacement drive 8a is an actuator for predefining an illumination setting when illuminating the object 5.

In addition to the displacement drive 8a, the metrology system 2 has an interchange holder 8b, by way of which it is possible to exchange the respective sigma stop 8 for an exchange sigma stop 8′. The interchange holder 8b makes it possible to transfer the sigma stop 8 currently being used in each case into a stop magazine and to select the interchange sigma stop from the stop magazine and to transfer this selected sigma stop to the location of the current sigma stop in the illumination optical unit pupil plane 9.

After reflection at the object 5, the illumination or imaging light 1 enters the imaging optical unit or projection optical unit 10 of the optical measurement system of the metrology system 2. In a manner analogous to the illumination aperture, there is a projection optical unit aperture predefined by an NA aperture stop 11 in an entrance pupil 12 of the projection optical unit 10 in FIG. 1.

The entrance pupil 12 is optically conjugate with respect to an illumination pupil of the illumination optical unit 7.

FIG. 3 shows, in an illustration similar to FIG. 2, once again a plan view of the NA aperture stop 11.

Webs 11₁, 11₂, 11₃, 11₄ connect a stop support of the NA aperture stop 11 to a central obscuration shadowing body 11₀ of the NA aperture stop 11. The obscuration shadowing body 11₀ simulates a central obscuration of the imaging optical unit of the optical production system to be simulated.

The stop material of the stops 8, 11 can be metal.

The entrance pupil 12 is one example of a projection optical unit pupil plane of the projection optical unit 10. The NA aperture stop 11 can also be arranged in an exit pupil of the projection optical unit 10. The NA aperture stop 11 is displaceable by way of a displacement drive 13 in the projection optical unit pupil plane 12, that is to say parallel to the xy-plane, in a defined fashion. The displacement drive 13 is also an actuator for predefining the illumination setting.

Typically, the sigma aperture stop 8 and the NA aperture stop 11 are aligned in such a way relative to one another that both stops are struck centrally by a central light ray of the illumination light 1 and the reflection at the test structure 5. The sigma aperture stop 8 and the NA aperture stop 11 can be centered relative to one another.

The imaging optical unit 10 to be measured serves for imaging the object 5 towards a spatially resolving detection device 14 of the metrology system 2. The detection device 14 is designed for example as a charge-coupled device (CCD) detector. A complementary metal-oxide-semiconductor (CMOS) detector can also be used. The detection device 14 is arranged in an image plane 15 of the projection optical unit 10.

The detection device 14 is signal connected to a digital image processing device 17.

A pixel spatial resolution of the detection device 14 in the xy-plane can be predefined in such a way that it is inversely proportional to the numerical aperture of the entrance pupil 12 to be measured, in the coordinate directions x and y (NAₓ, NA_{y}). In the direction of the x-coordinate, this pixel spatial resolution is regularly less than λ/2NAₓ, and, in the direction of the y-coordinate, it is regularly less than λ/2NA_{y}. In this case, A is the wavelength of the illumination light 1. The pixel spatial resolution of the detection device 14 can also be implemented with square pixel dimensions, independently of NAₓ, NA_{y}.

A spatial resolution of the detection device 14 can be increased or reduced by resampling. A detection device with pixels with different dimensions in the x- and y-directions is also possible.

The object 5 is carried by an object holder or a holder 18. The holder 18 can be displaced by way of a displacement drive or actuator 19, on the one hand parallel to the xy plane and on the other hand perpendicularly to this plane, that is to say in the z-direction. The displacement drive 19, as also the entire operation of the metrology system 2, is controlled by a central control device 20, which, in a way that is not represented any more specifically, is signal-connected to the components to be controlled.

The optical set-up of the metrology system 2 serves for the most exact possible simulation or emulation of an illumination and an imaging in the course of a projection exposure of the object 5 during the projection-lithographic production of semiconductor components. The optical measurement system of the metrology system 2 serves to simulate the illumination and imaging properties and in particular the target wavefront of the imaging optical production system of the projection exposure apparatus used in this case.

FIG. 1 shows various possible arrangement planes of the test structure 5 in the region of the object plane 4, in each case using a dashed line. During the operation of the metrology system 2, the test structure 5 is illuminated at different distance positions zₘ of the test structure 5 relative to the object plane 4 using the illumination angle distribution respectively predefined by the subaperture 10ᵢ, and an intensity I(x,y,zₘ) is recorded in spatially resolved fashion in the image plane 15 for the respective distance position zₘ. This measurement result I(x,y,zₘ) is also referred to as an aerial image.

The number of focal planes zₘ can be between two and twenty, for example between ten and fifteen. In this case, there is a total displacement in the z-direction over several Rayleigh units (NA/λ²).

In addition to the entrance pupil 12, FIG. 1 also moreover schematically represents an exit pupil 21 of the projection optical unit 13. The entrance pupil 12 and the exit pupil 21 of the imaging optical unit 10 are both elliptical. Alternatively, the two pupils 12, 21 can also have a round boundary.

The imaging optical unit 10 of the metrology system 2 is isomorphic, that is to say it has the same imaging scales in the x- and in the y-directions.

FIG. 1 shows, at the bottom, three measurement results of the detection device 14, once again in an xy-plan view, with the central measurement result showing the image representation of the test structure 5 in the case of an arrangement in the object plane 4 and the other two measurement results showing the image representations in which the test structure 5 has been displaced in comparison with the z-coordinate of the object plane 4, once in the positive z-direction and once in the negative z-direction. An aerial image of the test structure 5 arises from the totality of the measurement results assigned to the respective z-coordinates.

In the context of the simulation of the illumination and imaging properties of the optical production system during the illumination and imaging of the object 5 by use of the optical measurement system of the metrology system 2, a pupil stop shape of the sigma illumination stop 8 is optimized. Part of this optimization method is the determination of a match quality between the illumination and imaging properties of the optical production system, on the one hand, and the illumination and imaging properties of the optical measurement system of the metrology system 2, on the other hand, with the use of a specific stop shape of the sigma stop 8. A value of at least one merit function is calculated in the context of this match quality determination. Said merit function is influenced by a comparison of optical illumination and imaging parameters between a pupil overlap region of an illumination pupil and an imaging pupil of the optical production system, on the one hand, and a corresponding pupil overlap region of an illumination pupil with a used stop shape of the sigma stop 8 and an imaging pupil with a used NA aperture stop 11 of the optical measurement system.

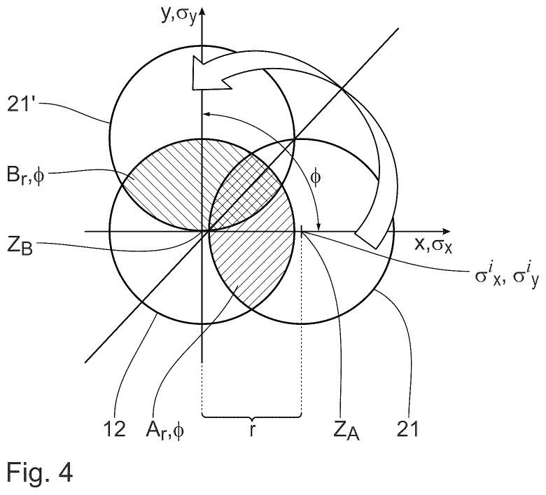

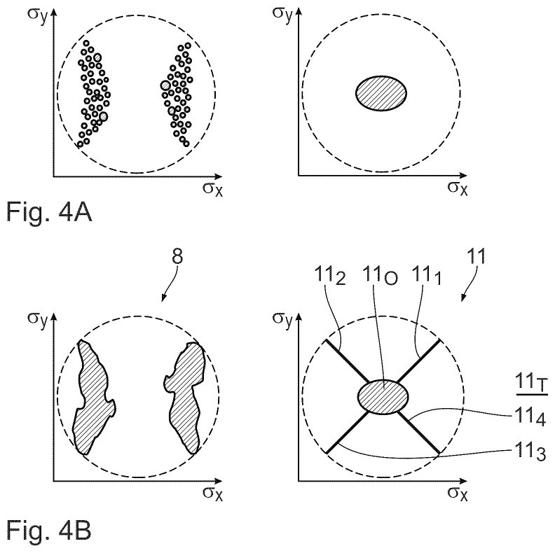

FIG. 4 shows such a pupil overlap region A_{r.ϕ} between an illumination pupil, which can be the entrance pupil 12, and an imaging pupil, which can be the exit pupil 21.

A center z_{Ar.ϕ} of the exit pupil 21 lies at Cartesian coordinates σₓⁱ, σ_{y}ⁱ. Instead of Cartesian coordinates σₓ, σ_{y}, it is also possible to choose polar coordinates, likewise illustrated in FIG. 4. In this case, σ_{ϕ} denotes the distance between a center z_{B} of the illumination pupil 12 and the center z_{A} of the exit pupil 21. Φ denotes the angle between the distance σ_{ϕ} and for example the σ_{y}-axis, as depicted in FIG. 4. In the case illustrated, ϕ is 90°.

In the context of determining the match quality with the aid of such a pupil overlap region A_{r.ϕ}, the overlap at various support points σₓⁱ, σ_{y}ⁱ that are scanned is assessed. The following assessment terms are used in this case:

$${D}_{r , ϕ} = {\int }_{{A}_{r , ϕ}} d {σ}_{x} d {σ}_{y} I ( {σ}_{x} , {σ}_{y} ) \qquad ( 1 )$$

$${T}_{r , ϕ} = {\int }_{{A}_{r , ϕ}} d {σ}_{x} d {σ}_{y} {σ}_{ϕ} ( {σ}_{x} , {σ}_{y} ) I ( {σ}_{x} , {σ}_{y} ) \qquad ( 2 )$$

D here is a term describing a simple summation of the intensities I(σₓ,σ_{y}) over the respective pupil overlap region A_{r.ϕ}. This D term (according to equation (1)) correlates with an image dimension CD (critical dimension), i.e. a width of a structure along a predefined direction.

In association with the definition of the parameter CD, reference is made to U.S. Pat. No. 9,176,390 B.

The T term (according to equation (2)) represents an integral over the overlap region A, said integral again being weighted with the distance value σ_{ϕ}. For this formulation of the T term, it is assumed for simplification that the exit pupil 11 or 21, respectively, has no apodization. This T term correlates with the imaging parameter imaging telecentricity. This can include a sensitivity of an object structure offset as a function of a defocus position of a substrate onto which the object is imaged.

For a given pupil stop shape of the sigma stop 8, the following optimization specifications are applied when determining the match quality for all possible overlap regions A_{r.ϕ}:

$${D}_{r , ϕ}^{d c} - {D}_{r , ϕ}^{t} = 0 for all value pairs r , ϕ \qquad ( 3 )$$

$${T}_{r , ϕ}^{d c} - {T}_{r , ϕ}^{t} = 0 for all value pairs r , ϕ \qquad ( 4 )$$

In this case, dc stands for the respective design candidate, i.e. for the currently considered stop shape of the sigma stop 8. t stands for the target illumination pupil of the optical production system, i.e. in particular of a projection exposure apparatus in the form of a scanner.

The optimization specifications in accordance with equations (3) and (4) are not attained as a rule. When determining the match quality, the stop shape of the design candidate dc is varied until the optimization specifications (3), (4) yield minimum values.

Besides the optimization variables D and T, further variables correlated with further illumination and/or imaging parameters can also be used when determining the match quality. One example of such a variable is:

$$H {V}_{r , ϕ} = {D}_{r , ϕ} - {D}_{r , ϕ - 9 {0}^{∘}} = {\int }_{{A}_{r , ϕ}} d {σ}_{x} d {σ}_{y} I ( {σ}_{x} , {σ}_{y} ) - {\int }_{{B}_{r , ϕ}} d {σ}_{x} d {σ}_{y} I ( {σ}_{x} , {σ}_{y} ) \qquad ( 5 )$$

This HV term correlates with an imaging variable “HV asymmetry”, which quantifies a difference in the critical dimensions (CDs) along a vertical and along a horizontal dimension. The HV term may be of interest depending on the structures to be imaged on the object 5; for example in the case of horizontal or vertical lines to be imaged, in particular having the same periodicity and the same target CD, or else in the case of so-called contact holes, i.e. structures having an xy aspect ratio in the region of 1. An HV asymmetry can then be understood as the difference between the two CDs, i.e. CDₙ-CDᵥ in the case of horizontal (h) and vertical (v) lines or CDₓ-CD_{y} in the case of contact holes having extents in the x- and y-directions.

Ascertaining the HV term according to equation (5) above involves calculating the difference between two D terms according to equation (1) at the location of two defined overlap regions A_{r.ϕ} and B_{r.ϕ} which are rotated with respect to one another by 90° about the coordinate origin z_{B} (cf. FIG. 4). In order to calculate the integral in the overlap region B, the overlap between for example the entrance pupil 12 and an exit pupil 21′ correspondingly rotated by 90° is taken into consideration.

For the HV term, too, there is then a corresponding optimization specification:

$$H {V}_{r , ϕ}^{d c} - H {V}_{r , ϕ}^{t} = 0 for all value pairs r , ϕ \qquad ( 6 )$$

After comparison calculation has been carried out, the overlap regions A_{r.ϕ} used cover the entire illumination pupil of, on the one hand, the optical production system and, on the other hand, the illumination optical unit 7 of the metrology system 2.

FIGS. 4A and 4B show two pupil pairs of, on the one hand, the optical production system (FIG. 4A) and, on the other hand, the optical measurement system of the metrology system 2 (FIG. 4B), which are compared with one another in the context of the match quality determination explained above in association with, in particular, FIG. 4.

FIG. 4A shows on the left an illumination of an illumination pupil for an x-dipole illumination setting. FIG. 4A shows on the right an exit pupil of the projection optical unit of the optical projection system with a central, approximately elliptical pupil obscuration.

The illumination setting to be simulated (cf. FIG. 4A on the left) of the optical production system can be composed of a multiplicity of individual spots in the illumination pupil, corresponding to a faceted configuration of an illumination optical unit of the optical production system, for example a configuration having a field facet mirror and a pupil facet mirror or a configuration in which a micro-electromechanical system (MEMS) mirror configuration is used within the illumination optical unit. The size of the respective individual spot in FIG. 4A on the left is a measure of the brightness of this individual spot, i.e. of the illumination intensity from the illumination direction assigned to this individual spot.

FIG. 4B shows on the left a target stop shape-obtained by use of the optimization method—of the sigma stop 8 for the simulation of the illumination and imaging properties of the optical production system with the illumination setting and the exit pupil according to FIG. 4A. FIG. 4B shows on the right the exit pupil of the imaging optical unit of the optical measurement system with the central obscuration that is produced by way of the NA stop 11 (also cf. FIG. 3).

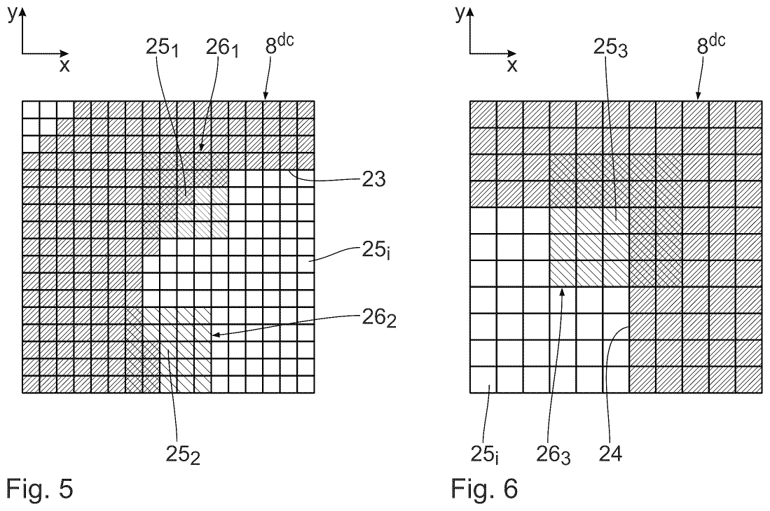

The optimization method for the pupil stop shape of the sigma stop 8 involves checking at least one fabrication boundary condition with regard to the respective design candidate of the stop shape. One example of such checking of the fabrication boundary conditions is explained in greater detail below with reference to FIGS. 5 and 6.

Consideration is given to a stop shape design candidate 8^{dc}, for which marginal check portions 23, 24 are illustrated in FIGS. 5 and 6. A resolution capability of the fabrication method is made clear by an extent of individual pixels 25ᵢ of the illustration according to FIGS. 5 and 6. Individual pixels 25ᵢ shown dark or hatched represent the possibly continuous stop material that blocks illumination/imaging light 1, and open individual pixels 25ᵢ represent a possibly continuous stop opening (transmission of the illumination/imaging light).

In the context of the checking method, the entire stop shape design candidate 8^{dc}, which is also referred to as starting or modification stop shape, is thus described as a regular bitmap in a pixel discretization.

In order to define a rounding of the respective check portion 23, 24, i.e. a curvature thereof, locally in a pixel-based manner, surrounding regions having a defined radius r are evaluated for each pixel 25ᵢ of the bitmap. This is illustrated for the pixels 25₁, 25₂ and 25₃ in FIGS. 5 and 6. The respective surrounding pixel region 26₁, 26₂, 26₃ evaluated, which is highlighted with different hatching, is square and has an extent of 5 individual pixels 25; in each case along both coordinates x, y. The central individual pixel to be considered, e.g. 25₁, and the surrounding pixel regions, for example 26₁, are arranged in rows and columns.

The following specification is checked during the evaluation:

Rounded-up sum of the individual pixels 25; within the respective pixel region 26; around the considered individual pixel with the opposite state “stop material” or “stop opening” with respect to said considered, central individual pixel is less than (2r+1)²/2.

For r=2, this sum must therefore be less than 13 since the comparative number is always an integer and, insofar as (2r+1)²/2 does not yield an integer, is rounded up to the next higher integer.

The corresponding evaluation reveals that the aforementioned specification is satisfied for the individual pixels 25₁ and 25₂ since the individual pixel 25₁ has stop material and nine individual pixels 25₁ representing stop openings are present in the pixel region 26₁, with the result that the specification “number less than 13” is satisfied, and since this is correspondingly satisfied for the individual pixel 25₂ (=stop opening) as well (number of individual pixels 25₁ in the pixel region 26₂ composed of stop material=8, i.e. less than 13).

This requirement is not satisfied for the individual pixel 25₃ since the latter represents a stop opening and a total of 16 individual pixels 25ᵢ representing stop material are present in the pixel region 26₃.

A check is thus made to establish whether the pixel regions 26ᵢ, i.e. the surrounding regions around the respective central individual pixel 25ᵢ, with sufficient probability behave just like the central region in regard to transmission of the illumination light.

The checking of the fabrication boundary conditions in accordance with this method thus reveals that it is possible to fabricate the marginal check portion 23 in the region of the individual pixels 25₁ and 25₂, but not the marginal check portion 24 in the region of the individual pixel 25₃. These fabrication boundary conditions are correspondingly checked for all the individual pixels 25ᵢ. The requirement that the specification explained above must be satisfied for all the individual pixels 25ᵢ then yields a fabricable stop shape for the sigma stop 8. The specification formulated locally for a respective check portion 23, 24 reveals that the respective stop shape of the stop shape design candidate 8^{dc} is varied only locally, and so in each case only a correspondingly small check portion of the entire stop shape has to be checked for fabricability.

A minimum hole diameter and for example a minimum stop web width can be predefined by way of the choice of the radius r.

When checking the fabrication boundary conditions, it is also possible to take account of an oblique illumination of the sigma stop, in the case of which an elliptical shape of the sigma stop 8 results in a round entrance pupil 12, for example. In this regard, in the case of the bitmap representation from FIGS. 5 and 6, an x- and y-extent of the individual pixels 25ᵢ can be chosen such that they are not identical to one another.

When determining the match quality between the illumination and imaging properties of the optical production system, on the one hand, and those of the optical measurement system of the metrology system 2, on the other hand, a field dependence of the object illumination of the optical production system can be taken into account. This then takes account of the fact that, in the optical production system, an object point is impinged on with a different intensity distribution of the illumination light over the illumination angles compared with an object point spaced apart therefrom.

This taking account of field variation can be effected by the target pupils taken into account (terms I′ for an illumination intensity impingement of the coordinates of the illumination pupil of the optical production system) being replaced by a target pupil field average value averaged over the entire object field 3. Alternatively, it is possible to minimize the optimization specifications according to equations (3), (4) and (6) above for all field coordinates, in particular for all x-field coordinates perpendicular to an object displacement direction y during the scanning of the optical production optics. Accordingly, field-dependent boundaries of the pupil overlap regions, A_{r.ϕ.x}, may then also arise.

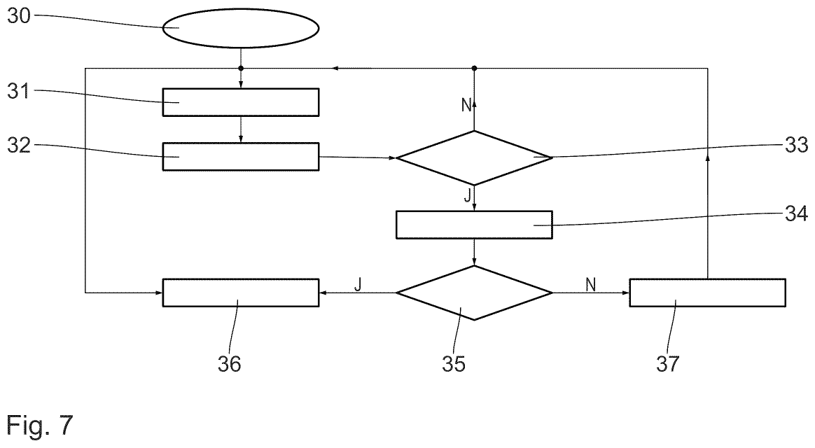

One example of an entire method for optimizing a pupil stop shape of the sigma stop 8 for simulating the illumination and imaging properties of the optical production system during the illumination and imaging of the object 5 by use of the optical measurement system of the metrology system 2 is explained below with reference to the flowchart according to FIG. 7.

In a predefining step 30, firstly a starting stop shape of the sigma stop 8, 8^{dc}, is selected as an initial design candidate for the simulation.

In the context of the optimization, this starting stop shape 8^{dc} is modified in a modifying step 31, such that a modification stop shape 8^{dcnew} that is slightly changed in regard to its boundary shape arises in a producing step 32.

In a checking step 33, a check is then made to establish whether this modification stop shape 8^{dcnew} satisfies at least one fabrication boundary condition with regard to the fabrication of this modification stop shape 8^{dcnew}. This can be done with the aid of the checking method explained above with reference to FIGS. 5 and 6. If the checking step reveals that at least one marginal check portion 23, 24 of the modification stop shape 8^{dcnew} does not satisfy the fabrication boundary conditions (decision “N” of the checking step 33), the modification step 31 and the producing step 32 are repeated. This is done until the checking step 33 for a modification stop shape 8^{dcnew} then given reveals compliance with the predefined fabrication boundary conditions (decision “Y” of the checking step 33).

A determining step 34 then involves determining the match quality between the illumination and imaging properties of the optical production system and the illumination and imaging properties of the optical measurement system. This is done with the aid of the match quality determination explained above in particular with reference to FIG. 4 and equations (1) to (6).

A merit function E can be used during the match quality determination since, in general, the match specifications according to equations (3), (4) and (6) do not all become 0 at the same time. This merit function can be written as weighted error minimization in the usual way as:

$$E ( I ( {σ}_{x} , {σ}_{y} ) ) = {w}_{D} {\sum }_{i , ϕ} {( {D}_{i , ϕ} ( I ( {σ}_{x} , {σ}_{y} ) ) - {D}_{i , ϕ} ( {I}^{t} ( {σ}_{x} , {σ}_{y} ) ) )}^{2} + {w}_{T} {\sum }_{i , ϕ} {( {T}_{i , ϕ} ( I ( {σ}_{x} , {σ}_{y} ) ) - {T}_{i , ϕ} ( {I}^{t} ( {σ}_{x} , {σ}_{y} ) ) )}^{2} + \qquad ( 7 )$$

I here denotes the stop shape of the sigma stop 8^{dcnew} which is intended to be assessed by means of the merit function. It denotes the target illumination pupil of the optical production system, this being the intended target of optimization. D and T denote the assessment terms discussed above in association with equations (3) and (4). In addition, the merit function E can for example also be extended by the assessment term HV (cf. equations (5) and (6)).

The merit function E can additionally be extended by the requirement for a minimum transmission of the sigma stop 8 dcnew

Besides the target illumination pupil of the optical production system, the determining step 34 can also be influenced by a pupil transfer function of the optical production system and a pupil transfer function of the optical measurement system of the metrology system 2.

For this purpose, the D term defined above in association with equation (1) can be written as follows:

$${D}_{r , ϕ} = {\int }_{- ∞}^{+ ∞} {\int }_{- ∞}^{+ ∞} d {σ}_{x} d {σ}_{y} I ( {σ}_{x} , {σ}_{y} ) {P}_{r , ϕ} ( {σ}_{x} , {σ}_{y} )$$

P here is an apodization function, i.e. an energetic proportion of the pupil transfer function.

An apodization of the exit pupil 11 or 21, respectively, can then be taken into account by this means.

In the course of the determining step 34, compliance with an optimization criterion is queried in an optimization query step 35. One example of such an optimization criterion is the Boltzmann criterion of simulated annealing:

$$satisfies r < P ( dc , {dc}_{n e w} ) where P ( dc , {dc}_{n e w} ) = {e}^{- β ( E ( d {c}_{n e w} ) - E ( d c ) )}$$

In this case, r is a uniformly distributed random number from the interval [0,1[(the exact numerical value “1” is thus excluded in this interval) and β is a control parameter that increases further and further in the course of the simulated annealing optimization. E(dc_{new}) and E(dc) are the merit functions that arose for the stop shapes of the sigma stop 8 during the last and during the preceding optimization step.

Insofar as the Boltzmann criterion is satisfied, i.e. the optimization has not yet concluded (decision Y in the query step 35), the current stop shape 8^{dcnew} is set as initial stop shape 8de for the next modification, which is effected in a predefining step 36. The control parameter β is also increased in the predefining step 36. The optimization criterion is thus intensified in the context of the predefining step 36. Afterwards, the method continues with the modifying step 31 and steps 32 to 35 are repeated until the optimization query step 35 reveals that either the Boltzmann criterion is no longer satisfied or the control parameter β is greater than a predefined value (query result N in the query step 35).

If, therefore, the optimization criterion has then been attained in the optimization query step 35 (query result N), the sigma stop 8 with the target stop shape that occurred with the smallest merit function value E in the optimization is fabricated in a fabricating step 37.

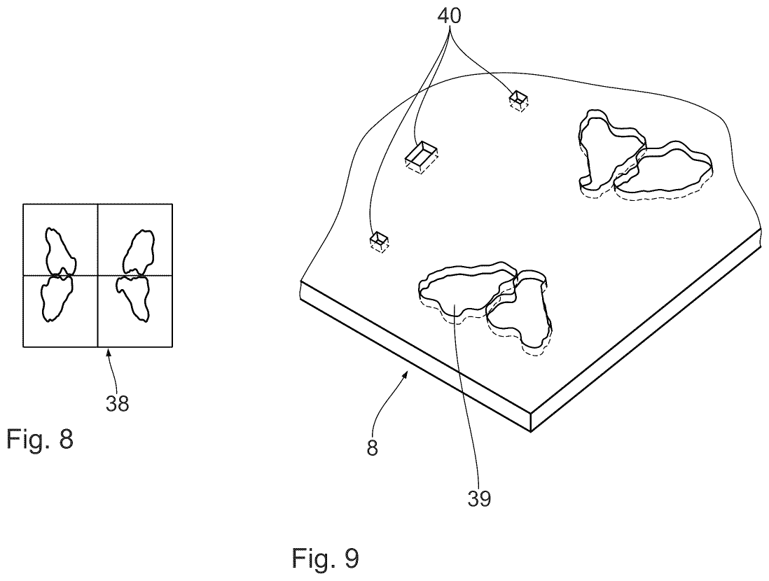

Such a target stop shape 38 in pupil coordinates of the pupil plane 9 is shown at the top left in FIG. 8.

The actual stop contour of the sigma stop 8 that results from this is illustrated at the bottom right in FIG. 9. A boundary 39 of stop openings of the sigma stop 8 which can be used for simulating a dipole illumination setting of the optical production system, for example, has a freeform configuration which is only slightly reminiscent of the actual dipole geometry of the illumination setting to be simulated.

In addition, FIG. 9 illustrates even further stop openings 40, which are alignment aids for positioning the sigma stop 8 in the pupil plane 9.

With the target stop shape of the sigma stop 8 that is then fabricated, after correctly aligned insertion into the optical measurement system, it is then possible for the metrology system 2 to measure the object or the test structure 5 under illumination and imaging conditions that are optimally modelled on those of the optical production system.

In some implementations, the calculations and processing of data (e.g., performing optimization) described in this document can be performed by one or more computers that include one or more data processors configured to execute one or more programs that include a plurality of instructions according to the principles described above. Each data processor can include one or more processor cores, and each processor core can include logic circuitry for processing data. For example, a data processor can include an arithmetic and logic unit (ALU), a control unit, and various registers. Each data processor can include cache memory. Each data processor can include a system-on-chip (SoC) that includes multiple processor cores, random access memory, graphics processing units, one or more controllers, and one or more communication modules. Each data processor can include millions or billions of transistors.

The methods described in this document can be carried out using one or more computers, which can include one or more data processors for processing data, one or more storage devices for storing data, and/or one or more computer programs including instructions that when executed by the one or more computers cause the one or more computers to carry out the processes. The one or more computers can include one or more input devices, such as a keyboard, a mouse, a touchpad, and/or a voice command input module, and one or more output devices, such as a display, and/or an audio speaker.

In some implementations, the one or more computing devices can include digital electronic circuitry, computer hardware, firmware, software, or any combination of the above. The features related to processing of data can be implemented in a computer program product tangibly embodied in an information carrier, e.g., in a machine-readable storage device, for execution by a programmable processor; and method steps can be performed by a programmable processor executing a program of instructions to perform functions of the described implementations. Alternatively or in addition, the program instructions can be encoded on a propagated signal that is an artificially generated signal, e.g., a machine-generated electrical, optical, or electromagnetic signal, that is generated to encode information for transmission to suitable receiver apparatus for execution by a programmable processor.

A computer program can be written in any form of programming language, including compiled or interpreted languages, and it can be deployed in any form, including as a stand-alone program or as a module, component, subroutine, or other unit suitable for use in a computing environment.

For example, the one or more computers can be configured to be suitable for the execution of a computer program and can include, by way of example, both general and special purpose microprocessors, and any one or more processors of any kind of digital computer. Generally, a processor will receive instructions and data from a read-only storage area or a random access storage area or both. Elements of a computer system include one or more processors for executing instructions and one or more storage area devices for storing instructions and data. Generally, a computer system will also include, or be operatively coupled to receive data from, or transfer data to, or both, one or more machine-readable storage media, such as hard drives, magnetic disks, solid state drives, magneto-optical disks, or optical disks. Machine-readable storage media suitable for embodying computer program instructions and data include various forms of non-volatile storage area, including by way of example, semiconductor storage devices, e.g., EPROM, EEPROM, flash storage devices, and solid state drives; magnetic disks, e.g., internal hard disks or removable disks; magneto-optical disks; and CD-ROM, DVD-ROM, and/or Blu-ray discs.

In some implementations, the processes described above can be implemented using software for execution on one or more mobile computing devices, one or more local computing devices, and/or one or more remote computing devices (which can be, e.g., cloud computing devices). For instance, the software forms procedures in one or more computer programs that execute on one or more programmed or programmable computer systems, either in the mobile computing devices, local computing devices, or remote computing systems (which may be of various architectures such as distributed, client/server, grid, or cloud), each including at least one processor, at least one data storage system (including volatile and non-volatile memory and/or storage elements), at least one wired or wireless input device or port, and at least one wired or wireless output device or port.

In some implementations, the software may be provided on a medium, such as CD-ROM, DVD-ROM, Blu-ray disc, a solid state drive, or a hard drive, readable by a general or special purpose programmable computer or delivered (encoded in a propagated signal) over a network to the computer where it is executed. The functions can be performed on a special purpose computer, or using special-purpose hardware, such as coprocessors. The software can be implemented in a distributed manner in which different parts of the computation specified by the software are performed by different computers. Each such computer program is preferably stored on or downloaded to a storage media or device (e.g., solid state memory or media, or magnetic or optical media) readable by a general or special purpose programmable computer, for configuring and operating the computer when the storage media or device is read by the computer system to perform the procedures described herein. The inventive system can also be considered to be implemented as a computer-readable storage medium, configured with a computer program, where the storage medium so configured causes a computer system to operate in a specific and predefined manner to perform the functions described herein.

The embodiments of the present invention that are described in this specification and the optional features and properties respectively mentioned in this regard should also be understood to be disclosed in all combinations with one another. In particular, in the present case, the description of a feature comprised by an embodiment-unless explicitly explained to the contrary-should also not be understood such that the feature is essential or indispensable for the function of the embodiment.

What is claimed is:

1. A method for optimizing a pupil stop shape for simulating illumination and imaging properties of an optical production system during the illumination and imaging of an object by use of an optical measurement system,
the optical measurement system comprising an illumination optical unit for the object having a pupil stop in the region of an illumination pupil having the pupil stop shape to be optimized, and an imaging optical unit for imaging the object,
comprising the following steps:
predefining a starting stop shape of the pupil stop as an initial design candidate for the simulation,
modifying the starting stop shape to give rise to a modification stop shape which is different from the most recently predefined stop shape,
checking at least one fabrication boundary condition with regard to fabrication of the modification stop shape and repeating the steps “modifying” and “checking” until the checking reveals compliance with the fabrication boundary condition,
determining a match quality between the illumination and imaging properties of the optical production system and the illumination and imaging properties of the optical measurement system as soon as the fabrication boundary conditions are complied with,
repeating the steps “modifying”, “checking” and “determining” until the match quality attains a predefined optimization criterion, which is checked by way of a query step, and
fabricating a target stop shape resulting from the attaining of the optimization criterion as an optimized pupil stop shape after attaining the optimization criterion.

2. The method of claim 1, wherein compliance with a local boundary condition is checked during the checking of the fabrication boundary condition for marginal check portions of the pupil stop shape, in which case, for surrounding regions of the respective check portion which are arranged around a central region, a check is made to establish whether these behave just like the central region in regard to transmission of illumination light, the local boundary condition being satisfied if a predefined proportion of the respective surrounding region behaves just like the central region.

3. The method of claim 2, wherein the central region and the surrounding regions are arranged as pixels in rows and columns.

4. The method of claim 1, wherein determining the match quality is influenced by an ascertainment of a match between an illumination and/or imaging pupil of the optical production system and an illumination and/or imaging pupil of the optical measurement system.

5. The method of claim 4, wherein determining the match quality is effected by calculating a value of a merit function influenced by a comparison of optical illumination and imaging parameters between
a pupil overlap region of an illumination pupil and an imaging exit pupil of the optical production system and
a corresponding pupil overlap region of an illumination pupil with used stop shape and an imaging aperture for predefining the imaging exit pupil of the optical measurement system
for a plurality of pupil overlap regions, each of which covers the entire illumination pupil.

6. The method of claim 5, wherein the following are used as optical illumination and imaging parameters:
an integral intensity of the illumination light which passes through the illumination pupil in the pupil overlap region and/or
an integral intensity—weighted with a telecentricity parameter—of the illumination light which passes through the illumination pupil in the pupil overlap region.

7. The method of claim 1, wherein as soon as the predefined optimization criterion is attained, an optimization routine is continued as follows:
intensifying the optimization criterion,
once again performing the steps “modifying”, “checking” and “determining” until the match quality attains the intensified optimization criterion, and
repeating the steps “intensifying” and “once again performing” until a termination criterion is attained, which is checked in the optimization query step.

8. The method of claim 1, wherein a dependence of a distribution of illumination angles of an illumination of the object over an illuminated object field is taken into account when determining the match quality.

9. A pupil stop, optimized by use of a method according to claim 1.

10. The pupil stop of claim 9, wherein the pupil stop shape is embodied with a freeform stop boundary.

11. A metrology system comprising at least one pupil stop, optimized by use of a method according to claim 1, wherein an optical measurement system of the metrology system comprises an illumination optical unit for the object having the optimized pupil stop in the region of an illumination pupil and an imaging optical unit for imaging the object.

12. The metrology system of claim 11, comprising an interchange holder for the pupil stop.

13. The metrology system of claim 11, configured for use in the simulation of the illumination-imaging properties of an optical production system having an anamorphic projection optical unit.

14. The metrology system of claim 11, wherein as part of the method of optimizing the at least one pupil stop, compliance with a local boundary condition is checked during the checking of the fabrication boundary condition for marginal check portions of the pupil stop shape, in which case, for surrounding regions of the respective check portion which are arranged around a central region, a check is made to establish whether these behave just like the central region in regard to transmission of illumination light, the local boundary condition being satisfied if a predefined proportion of the respective surrounding region behaves just like the central region.

15. The metrology system of claim 11, wherein as part of the method of optimizing the at least one pupil stop, determining the match quality is influenced by an ascertainment of a match between an illumination and/or imaging pupil of the optical production system and an illumination and/or imaging pupil of the optical measurement system.

16. The metrology system of claim 11, wherein as part of the method of optimizing the at least one pupil stop, as soon as the predefined optimization criterion is attained, an optimization routine is continued as follows:
intensifying the optimization criterion,
once again performing the steps “modifying”, “checking” and “determining” until the match quality attains the intensified optimization criterion, and
repeating the steps “intensifying” and “once again performing” until a termination criterion is attained, which is checked in the optimization query step.

17. The metrology system of claim 11, wherein as part of the method of optimizing the at least one pupil stop, a dependence of a distribution of illumination angles of an illumination of the object over an illuminated object field is taken into account when determining the match quality.

18. The pupil stop of claim 9, wherein as part of the method of optimizing the pupil stop, compliance with a local boundary condition is checked during the checking of the fabrication boundary condition for marginal check portions of the pupil stop shape, in which case, for surrounding regions of the respective check portion which are arranged around a central region, a check is made to establish whether these behave just like the central region in regard to transmission of illumination light, the local boundary condition being satisfied if a predefined proportion of the respective surrounding region behaves just like the central region.

19. The pupil stop of claim 9, wherein as part of the method of optimizing the pupil stop, determining the match quality is influenced by an ascertainment of a match between an illumination and/or imaging pupil of the optical production system and an illumination and/or imaging pupil of the optical measurement system.

20. The pupil stop of claim 9, wherein as part of the method of optimizing the pupil stop, as soon as the predefined optimization criterion is attained, an optimization routine is continued as follows:
intensifying the optimization criterion,
once again performing the steps “modifying”, “checking” and “determining” until the match quality attains the intensified optimization criterion, and
repeating the steps “intensifying” and “once again performing” until a termination criterion is attained, which is checked in the optimization query step.
